(19) United States
(12) Patent Application Publication
(10) Pub. No.: US 2002/0125530 A1
(43) Pub. Date: Sep. 12, 2002

(54) High voltage metal oxide device with multiple p-regions

(75) Inventors: Mohamed Imam, Tempe, AZ (US); Evgueniy N. Stefanov, Vieille Toulouse (FR); Zia Hossain, Tempe, AZ (US); Mohammed Tanvir Quddus, Tempe, AZ (US); Joe Fulton, Chandler, AZ (US); Jeff Hall, Phoenix, AZ (US)

Correspondence Address: Robert D. Atkins, ON Semiconductor, Patent Administration Dept - MD A230, P.O. Box 62890, Phoenix, AZ, 85082-2890, US

(73) Assignee: Semiconductor Components Industries, LLC.

(21) Appl. No.: 09/799,595

(22) Filed: Mar. 7, 2001

(51) Int. Cl. H01L 21/336; H01L 29/76; H01L 29/94; H01L 31/062; H01L 31/113; H01L 31/119

(52) U.S. Cl. 257/343; 438/306

(57) ABSTRACT

A high voltage MOS device (100) with multiple p-regions (110) is disclosed. The device comprises a plurality of p-regions (110) arranged as multiple segments both perpendicular to and parallel to current flow. The p-regions (110) allow for depletion in all directions when the device is blocking voltage, leading to a high breakdown voltage. During operation, the multiple regions have multiple conductivity channels (118) of high conductivity that allows current to flow, thus enhancing on-resistance.

### FIELD OF THE INVENTION

The present invention relates to high voltage MOS devices and more specifically to a method for high voltage MOS device with multiple p-regions.

### BACKGROUND OF THE INVENTION

When designing high voltage metal oxide (MOS) devices two criteria must be kept in mind. First, the devices should have a very high breakdown voltage (V_{BD}). Second, the device, when operating, should have as low an on-resistance (RDS_{ON}) as possible. One problem is that techniques and structures that tend to maximize V_{BD} tend to adversely affect RDS_{ON} and vice versa.

To overcome this problem, different designs have been proposed to form devices with acceptable combinations of V_{BD} and RDS_{ON}. One such family of devices is fabricated according to the reduced surface field (RESURF) principle. These devices utilize an extended drain region (in one embodiment a n-well) to support high off-state voltage (V_{BD}). These devices have a maximum charge in the drain area of about 1×10¹² cm⁻² before avalanche breakdown occurs. This maximum charge sets the lowest RDS_{ON} since RDS_{ON} is proportional to the charge in the drain region.

To help alleviate this problem, some devices utilize a top layer of a conductivity type opposite the extended drain region inside the drain region (in one embodiment a p-layer). The top layer allows for a drain region having approximately double the charge than previous designs, which decreases the RDS_{ON}. The top layer helps to deplete the extended drain when the extended drain is supporting high voltage, thus allowing for high breakdown voltage. Typically, the top layer is formed as one solid layer. However, there are also devices where the top layer is formed as stripes surrounded by conductivity channels formed by the drain region. In one embodiment, the top layers are formed parallel to current flow and in another the layers are perpendicular to current flow.

One drawback to this approach is that solid top layers can only deplete downwards while striped regions only deplete downwards and towards other striped regions in one direction. What is needed is top layers that can deplete in all directions, which in turn increases break down voltage and as a result helps to reduce RDS_{ON}.

### BRIEF DESCRIPTION OF THE DRAWINGS

For a more complete understanding of the present invention and advantages thereof, reference is now made to the following descriptions, taken in conjunction with the following drawings, in which like reference numerals represent like parts, and in which:

FIG. 1 is a cross-sectional side view of the device;

FIG. 2 is a cross-sectional overhead view of the device taken along line 2-2 of FIG. 1;

FIG. 3 is a cross-sectional overhead view of another embodiment of the device;

FIG. 4 is a cross-sectional side view of the device with an enhanced n-well;

FIG. 5 is a cross-sectional side view of the device with multiple layers of p-regions; and

FIGS. 6-8 are cross-sectional side views of the device at various stages in the manufacturing of the device.

### DETAILED DESCRIPTION OF THE DRAWINGS

The present invention relates to high voltage MOS devices that have a high breakdown voltage and low on-resistance. While specific embodiments are described below using n-channel devices, the present invention also pertains to p-channel devices, which may be formed by reversing the conductivity of the described regions and layers.

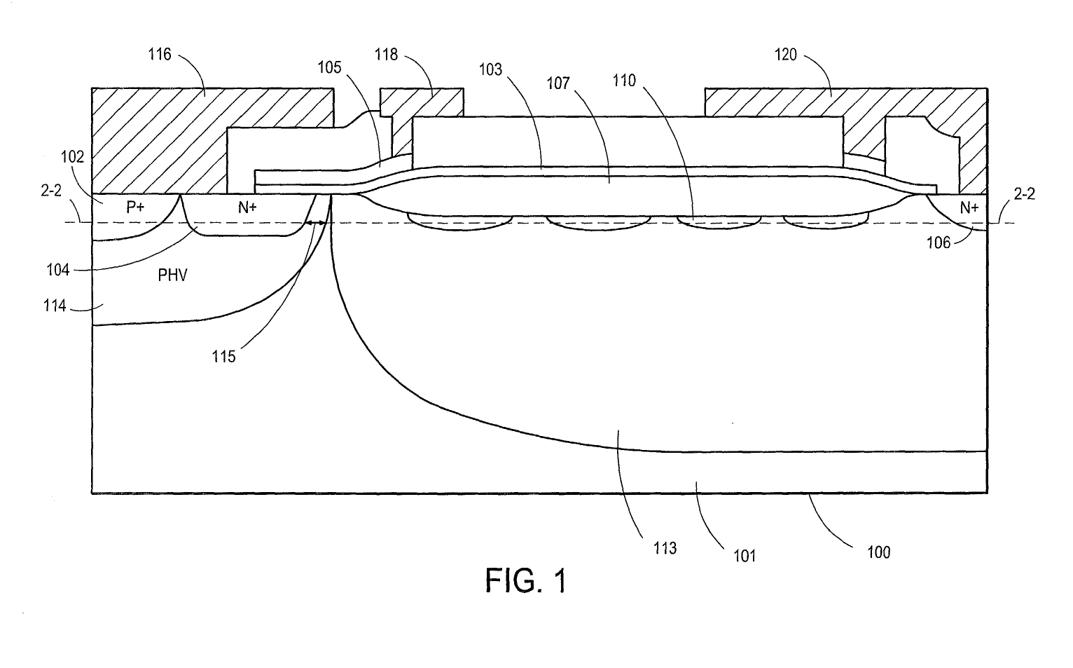

FIG. 1 is a cross-sectional side view of device 100. Illustrated is a lightly doped p-type substrate region 101. A N+ source diffusion region 104 is formed in substrate region 101. A P+ diffusion region 102 is formed adjacent to N+ source diffusion region 104. The P+ diffusion region 102 increases the integrity of the source to substrate connection as well as reduces the device's susceptibility to parasitic bipolar effects. Associated with N+ source diffusion region 104 and P+ region 102 is a source electrode 116, which provides electrical contact to the N+ source region 104 and P+ region 102. Also illustrated is a gate 105 (typically comprising polysilicon) formed over an insulating layer 103 (comprising silicon dioxide or some other insulating dielectric material) and a gate contact 118.

A drain diffusion region 106 is connected electrically to drain contact 120. Drain contact 120 may comprise a number of conductive metals or metal alloys. An optional diffused P region 114 may be formed to enclose P+ region 102 and N+ source region 104. The optional diffused P region 114 is a high voltage P-region (PHV) and helps to reduce the device's susceptibility to drain-to-source punch through as well as helps to provide an appropriate threshold voltage. A device that includes the optional diffused P-region 114 is known as a double diffused metal oxide device (DMOS device). When the source contact and drain contact are on the same side, the device is a lateral DMOS or LDMOS device. Also illustrated is a channel region 115 extending from the N+ source region 104 to the end of the diffused p region 114.

A n-well region 113 comprising a region of high doping concentration is formed in substrate 101. In the n-well region 113, in one embodiment, the charge can approach 2×10¹² cm⁻². P-regions 110 are formed inside n-well 113 for charge balancing. P-regions 110 are illustrated adjacent to the top of n-well region 113. However, p-regions 110 may be formed deeper inside n-well 113 or multiple layers of p-regions can be distributed throughout n-well 113. P-region 110 allows for downward depletion when voltage is blocked as well as depleting in all directions including towards other p-regions. The downward depletion, along with the upward depletion from the bottom of n-well 113, allows for a high breakdown voltage. P-regions 110 can be grounded or left floating. A layer of field oxide 107 can be provided over the n-well 113 to protect the n-well 113 from mobile contaminants.

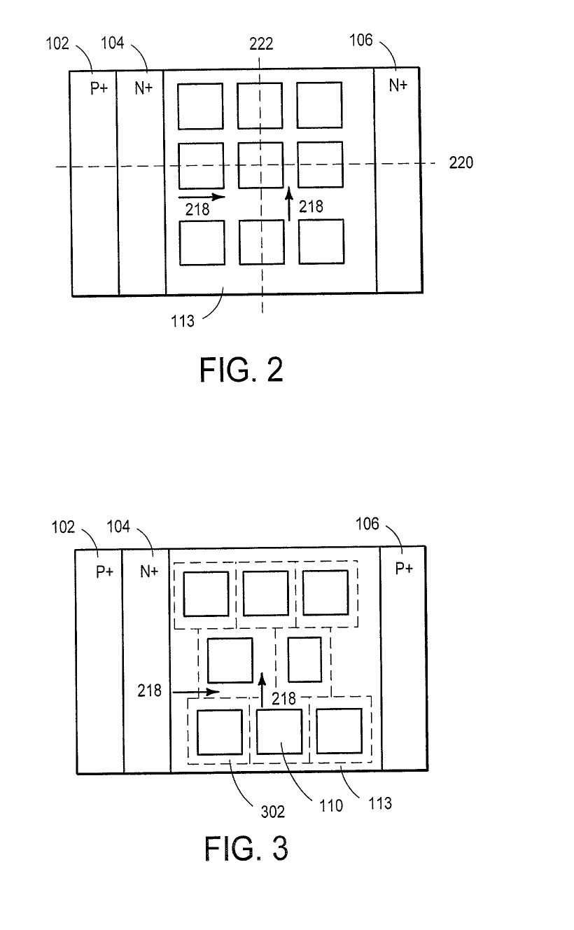

FIG. 2 is a cross-sectional overhead view of the device in FIG. 1 taken along line 2-2. Illustrated is a device 100 having a source region 104, an adjacent p-diffusion region 102, and a drain diffusion region 106. Multiple p-regions 110 are formed in the drift region that is enclosed by an n-well 113. Conductivity channels 218 separate the individual p-regions 110. P-regions 110 are formed such that there are multiple individual p-regions 110 segments both parallel and perpendicular to current flow 114. P-regions 110 in FIG. 1 are shown as squares or rectangles. However, other shape p-regions, regular or otherwise can be used such as hexagonal, circular, rhomboid and the like. P-regions 110 will diffuse downward but will also diffuse in all directions toward each other. The presence of these p-regions 110 allows for higher breakdown voltage. Also, the embodiment shown in FIG. 1 has conductivity channels 218 in the same direction of the current flow 204 (from source to drain) and conductivity channels perpendicular to the current flow. These conductivity channels are formed by the highly doped n-well region 113. The highly doped n-well region 113 allows for current to flow from the source region 104 to the drain region 106 in more conductivity channels than in lower doped regions, lowering RDS_{ON}. In other embodiments, depending on the shape of the p-regions 110, the conductivity channels 218 may be essentially parallel and perpendicular to current flow with some deviation to conform to the shape and layout of the p-regions 110.

Also in FIG. 2, by observing a first line 220, which is drawn from a fixed point at the source region 104 to a fixed point at the drain region, it can be observed that there are multiple p-regions 110 along the first line 220. Similarly, by observing a second line 222 perpendicular to first line 220 it can be seen that there are multiple p-regions 110 along second line 222 as well. Line 220 is parallel to current flow and line 222 is perpendicular to current flow. Thus, in the present invention, there are a plurality of individual p-regions 110 both parallel and perpendicular to current flow observed at a fixed point. Each p-region 110 is separated by conductivity channels 218, which forms a path for current to flow. By increasing the number of paths for current to flow during operation, on-resistance is reduced.

FIG. 3 is a cross-sectional overhead view of the device where the p-regions 110 are offset. Again square p-regions 110 are illustrated as examples only. Other shapes and other arrangements of p-regions are possible. In FIG. 3, depletion regions 302 are shown. FIG. 1 shows the depletion that occurs in the n-well 113 when the device is blocking voltage. P-regions 110 need to be positioned such that the depletion region from each p-region 110 either touches or overlaps the depletion region from adjacent p-regions 110. Also, while FIG. 3 illustrates depletion around the p-regions 110, depletion occurs in all directions. Thus depletion will also occur downward towards the bottom of n-well 113.

Also in FIG. 3, even though the p-regions 110 are offset from one another, it can be observed that there are a plurality of conductivity channels 218 formed by n-well material that form a path for current flow. Thus, the p-regions 110 are surrounded by conductivity channels 218, which are both essentially parallel and perpendicular to current flow.

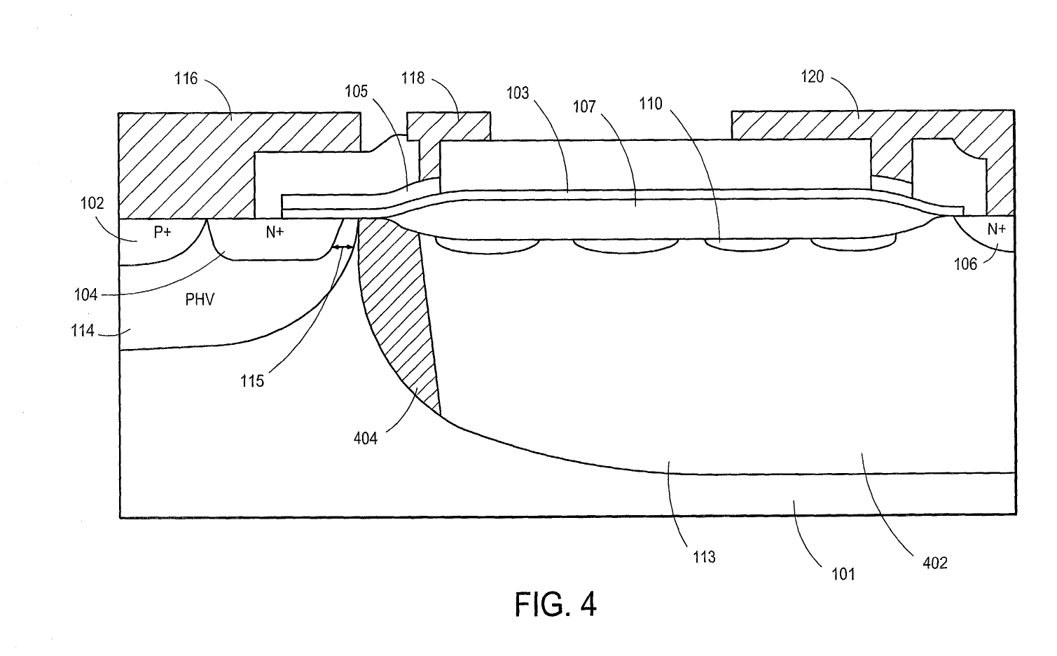

FIG. 4 is a cross-sectional side view of the device with an enhanced n-well. In FIG. 4, n-well 113 comprises a first region of high dopant concentration offset from a second region of lower dopant concentration. The regions are formed by performing two separate n-well implants. The first implant is a relatively low concentration implant. Then, a second implant of higher concentration is performed. The second implant is laterally offset from the first implant by a certain amount. The two implants form the two separate regions. Two separate regions allow for a lower concentration of dopants, under the gate region next to the channel region 115, which increases the depletion extension region into the n-well 113 and helps prevent premature breakdowns that occur at critical fields at the surface of the device. Illustrated in FIG. 4 is an n-well 113 having a first region 402 of high concentration laterally offset from a second region 404 of lower concentration.

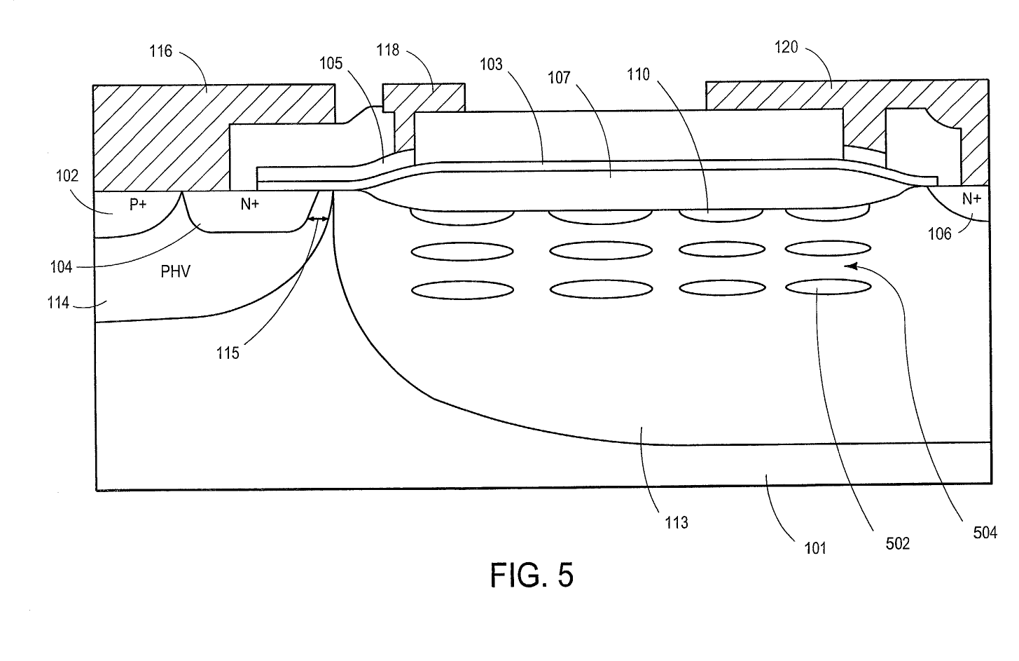

FIG. 5 is a cross-sectional side view of the device with additional p-regions 502 that are formed within n-well 113 and below p-regions 110. These additional p-regions are formed, for example, by high-energy ion implantation. This results in a n-well 113 with multiple p-regions 502 separated by conduction channels 504. The additional conduction channels allows for a lower on resistance by allowing for a large charge in each conduction channel.

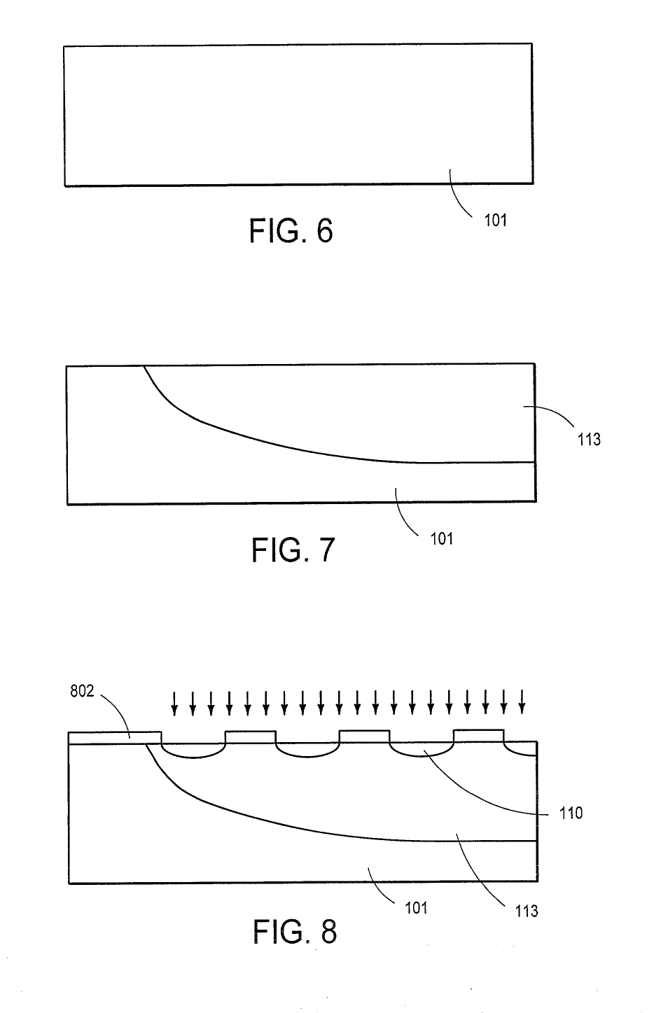

FIGS. 6 through 8 are cross-sectional side views of the device at various stages in an exemplary process to manufacture the device. First, as illustrated in FIG. 6, a p substrate is provided. Then, as illustrated in FIG. 7, a n-well implant is performed. In this step dopants 804 are implanted through a mask 802. A thermal cycle is performed to diffuse the n-well. Next, a p-top implant is performed through a mask. The mask 802 in this step will have multiple “openings” to form multiple islands of p-top layer 110 in n-well 113. The mask in FIG. 8 is a cross section showing only a few openings. The mask will have sufficient openings to produce multiple regions spread throughout the n-well region 113. A heating cycle is then performed to diffuse the p-top layer. These steps are illustrated in FIG. 8.

Then, an optional PHV implant and drive is performed. Then, the p-region in the PHV region is formed along with the n-type source and n-drain regions. After that a source/drain anneal is completed and any other necessary steps are performed. The final device is as illustrated in FIG. 1.

Thus, it is apparent that there has been provided, an improved semiconductor device. It should be understood that various changes, substitutions, and alterations are readily ascertainable and can be made herein without departing from the spirit and scope of the present invention as defined by the following claims.

What is claimed:

1. A high voltage MOS device comprising:
a substrate;
a first region of a first conductivity type formed in the substrate;
at least two regions of a second conductivity type formed in the first region such that current flows around each of the at least two regions.

2. The device of claim 1, wherein each of the at least two regions of a second conductivity type are formed at the surface of the first region.

3. The device of claim 1, wherein each of the at least two regions of the second conductivity type are in a regular pattern.

4. The device of claim 1, wherein each of the at least two regions of the second conductivity type are square shaped.

5. The device of claim 1, wherein the first region is an epitaxial region.

6. The device of claim 1, wherein the first region is a well region.

7. The device of claim 6, wherein the well region comprises a first area of high dopant concentration and a second area of low dopant concentration.

8. The device of claim 7, wherein the second area of low dopant concentration underlies a gate region adjacent to a channel region.

9. The device of claim 1 further comprising a diffused region of the second conductivity type, the diffused region surrounding a source region.

10. The device of claim 1, further comprising a plurality of layers of at least two regions of a second conductivity, wherein each layer is separated by a conductivity channel.

11. A method for manufacturing a MOS device comprising:
forming a substrate;
forming a first region of a first conductivity type in the substrate; and
implanting a plurality of regions of a second conductivity type in the first region such that each of the plurality of regions have current flowing around regions.

12. The method of claim 11, wherein the step of implanting further comprises forming the plurality of regions at the surface of the first region.

13. The method of claim 11, wherein the step of implanting further comprises implanting the regions of the second conductivity type in a regular pattern.

14. The method of claim 11, wherein the step of implanting further comprises implanting a plurality of regions that are square shaped.

15. The method of claim 11, wherein the step of forming a first region further comprises forming an epitaxial region.

16. The method of claim 11, wherein the step of forming the first region further comprises forming a well region.

17. The method of claim 16, wherein the step of forming a well region further comprises forming a first area of high dopant concentration and a second area of low dopant concentration.

18. The method of claim 17, wherein the step of forming a first area of high dopant concentration further comprises forming the second area underneath a gate region adjacent to a channel region.

19. The method of claim 11, further comprising the step of forming a diffused region of the second conductivity type surrounding a source region.

20. The method of claim 11, further comprising the step of forming a plurality of layers of the plurality of regions of a second conductivity, wherein each layer is separated by a conductivity channel.

21. A high voltage DMOS comprising:
a substrate;
a first region of a first conductivity type formed in the substrate;
a plurality of regions of a second conductivity type formed in the first region;
a plurality of conductivity channels surrounding the plurality of regions such that there are conductivity channels in all current flow directions;
a drain region formed within the first region;
a diffused region of the second conductivity type formed as a lightly doped, high voltage region; and
a source region formed within the diffused region.

22. The device of claim 21, wherein the plurality regions of a second conductivity type are formed at the surface of the first region.

23. The device of claim 21, wherein the plurality of regions of the second conductivity type are in a regular pattern.

24. The device of claim 21, wherein the first region is an epitaxial region.

25. The device of claim 21, wherein the first region is a well region.

26. The device of claim 25, wherein the well region comprises a first area of high dopant concentration and a second area of low dopant concentration.

27. The device of claim 26, wherein the second region of low dopant concentration underlies a gate region adjacent to a channel region.

28. The device of claim 21, further comprising a plurality of layers of a plurality of regions of a second conductivity, wherein each layer is separated by a conductivity channel.
